(19) United States
(12) Patent Application Publication
(10) Pub. No.: US 2020/0221575 A1
(43) Pub. Date: Jul. 9, 2020

(54) FULL-SCREEN DISPLAY PANEL

(71) Applicant: WUHANCHINASTAROPTOELECTRONICSSEMICONDUCTORDISPLAYTECHNOLOGYCOLTD, Wuhan, Hubei (CN)

(72) Inventors: Bin XU, Wuhan,Hubei (CN); Hongyu XU, Wuhan,Hubei (CN)

(21) Appl. No.: 16/467,992

(22) PCT Filed: Feb. 21, 2019
(86) PCT No.: PCT/CN2019/075639

§ 371 Date: Jun. 10, 2019

(30) Foreign Application Priority Data
Dec. 17, 2018 (CN) 201811544658.3

(51) Int. Cl. H05K 1/18; H01L 27/32; H01L 51/00

(52) U.S. Cl. CPC H05K 1/189; H05K 2201/10128; H01L 51/0097; H01L 27/3276

(57) ABSTRACT

A full-screen display panel is provided, comprising a main display section, and at least two bendable chip on panel (COP) circuit sections disposed on different lateral sides of the main display section. The main display section and the COP circuit sections are disposed on a flexible substrate. The COP circuit sections are bent rearwardly from one edge of the main display section to a backside of the main display section, thereby making each of the COP circuit sections attached to the backside of the main display section. Because the COP circuit sections are disposed on different lateral sides of the main display section, the full-screen display panel has sufficient edge regions for setting external compensation circuits and drive chips, thereby realizing the full-screen display panel with diverse functions.

### FIELD OF INVENTION

The present invention relates to a technical field of a display, in particular to a full-screen display panel.

### BACKGROUND OF INVENTION

In flat panel display technologies, organic light-emitting diode (OLED) displays have many advantages such as light and thin, active illumination, fast response, wide viewing angle, wide color gamut, high brightness, low power consumption, and good flexibility. Therefore, the OLED displays have aroused keen interest from both academe and industry and have gradually become the third generation display technology after liquid crystal displays (LCDs).

Consumers are increasingly demanding a high screen-to-body ratio of displays. Taking a mobile phone as an example, if the overall size of the mobile phone is large but the actual display area of the mobile phone is small, users of the mobile phone will be upset as if they were moving from a big house to a small house. As a result, consumers will continue to pursue mobile phones with larger screens and higher screen-to-body ratio. OLED displays with good flexibility play a vital role in realizing displays with high screen-to-body ratio.

With the development of display technology, a display effect of a display device is getting better and better, and giving people a good visual experience. However, due to the improvement of living standards, people's requirements for display devices are not limited to display effects, but also require display devices with diverse functions, such as augmented reality (AR) and virtual reality (VR).

To realize full-screen display devices with diverse functions, a plurality of sensors and cameras are disposed beneath a screen of the full-screen display devices or integrated into a screen of the full-screen display devices. The sensors include a fingerprint sensor, a proximity sensor, an ambient light sensor, and a face recognition sensor. As a result, it is necessary to set more external compensation circuits, and further need to set more edge regions for arranging the external compensation circuits and integrated chips (ICs). The conventional chip on panel (COP) method that the ICs are only disposed on a lower area of a display panel is no longer sufficient.

### SUMMARY OF INVENTION

An object of the present invention is to provide a full-screen display panel with sufficient edge regions for setting external compensation circuits and drive chips, thereby realizing the full-screen display panel with diverse functions.

To realize the above object, the present invention provides a full-screen display panel including a main display section, and at least two COP circuit sections disposed on different lateral sides of the main display section respectively.

The main display section and the COP circuit sections are disposed on a flexible substrate, and each of the COP circuit sections is bent rearwardly from one edge of the main display section to a backside of the main display section, thereby making each of the COP circuit sections attached to the backside of the main display section.

Each of the COP circuit sections includes a first COP circuit section disposed beneath the main display section, and a second COP circuit section disposed on a left side of the main display section or a right side of the main display section.

Both the first COP circuit section and the second COP circuit section are disposed on the backside of the main display section but do not overlap each other.

The main display section includes a thin film transistor (TFT) array layer disposed on the flexible substrate, and an OLED display layer disposed on the TFT array layer.

The full-screen display device further includes a plurality of functional devices disposed on the backside of the main display section or inside the main display section.

Each of the functional devices includes a camera and a plurality of sensors.

Optionally, the full-screen display device further includes a flexible circuit board disposed on the backside of the main display section, and the flexible circuit board is connected to the COP circuit sections.

The functional devices are disposed on the flexible circuit board on the backside of the main display section.

The functional devices are disposed inside an opening, and the opening is defined within the main display section.

A functional area is corresponding to an area of the plurality of the functional devices disposed on the main display section.

The COP circuit section is provided with a drive chip and an external compensation circuit for performing a sectional brightness compensation on the functional area.

The plurality of sensors include a fingerprint sensor, a proximity sensor, an ambient light sensor, and a face recognition sensor.

The flexible substrate is a polyimide substrate.

Advantageous Effects of the Present Invention:

The present invention provides a full-screen display panel including a main display section, and at least two COP circuit sections disposed on different lateral sides of the main display section respectively. The main display section and the COP circuit sections are disposed on a flexible substrate, and each of the COP circuit sections is bent rearwardly from one edge of the main display section to a backside of the main display section, thereby making each of the COP circuit sections attached to the backside of the main display section. Furthermore, the present invention provides a full-screen display panel with sufficient edge regions for setting external compensation circuits and drive chips, thereby realizing the full-screen display panel with diverse functions.

The detailed description of the present nvention and the accompanying drawings are to be understood, instead of limiting thereto.

### DESCRIPTION OF DRAWINGS

The technical solutions and other advantageous effects of the present invention will be apparent from the following detailed description of embodiments of the present invention.

In the drawings,

FIG. 1 is a plan view showing a backside of the full-screen display panel according to the present invention when COP circuit sections are unfolded.

FIG. 2 is a plan view showing a back side of the full-screen display panel according to the present invention when COP circuit sections are rearwardly bent to the back side of the full-screen display panel.

### DETAILED DESCRIPTION OF PREFERRED EMBODIMENTS

In order to further clarify the technical means and effects of the present invention, the following detailed description will be made in conjunction with the preferred embodiments of the present invention and the accompanying drawings.

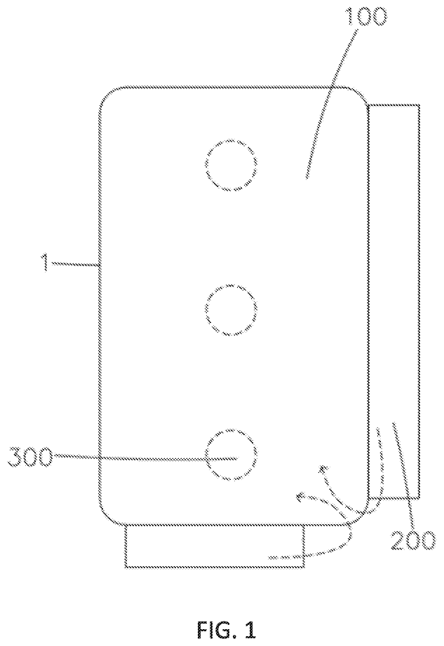

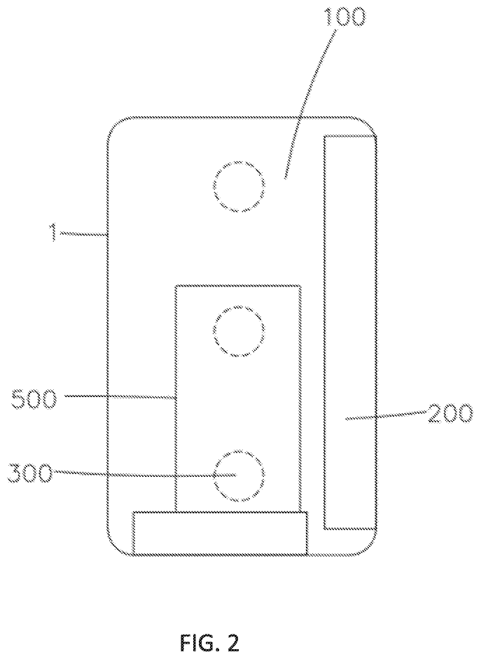

As shown in FIG. 1 and FIG. 2, the present invention provides a full-screen display panel comprising a main display section 100, at least two chip on panel (COP) sections 200 disposed on different lateral sides of the main display section 100 respectively, and a plurality of functional devices 300 disposed on a backside of the main display section 100 respectively or disposed in the main display section 100 respectively.

It should be noted, in the field of display, COP is a common method of arranging a chip. Specifically, COP is a method of directly arranging a drive chip on a display substrate, wherein the drive chip is connected to an effective display region of a display panel through an external circuit, thereby realizing all drive functions that the display panel needs.

The main display section 100 and the COP circuit sections 200 are disposed on a flexible substrate. Each of the COP circuit sections is bent rearwardly from one edge of the main display section to a backside of the main display section 100, thereby making each of the COP circuit sections 200 attached to the backside of the main display section 100. Two COP circuit sections 200 are disposed on different lateral sides of the main display section 100, thereby providing sufficient edge regions for setting external compensation circuits and drive chips, further realizing the full-screen display panel with diverse functions.

Specifically, the two COP circuit sections 200 are a first COP circuit section 210 and a second COP circuit section 220 respectively. The first COP circuit section 210 is disposed on a lower side of the main display section 100, and the second COP circuit section 220 is disposed on a left side of the main display section 100 or on a right side of the main display section 100.

Specifically, the first circuit section 210 and the second circuit section 220 are cut by laser cutting or other methods, thereby making the first circuit section 210 and the second circuit section 220 do not overlap each other on the backside of the main circuit section 100.

Specifically, the full-screen display panel of the present embodiment is a flexible OLED display panel. The main display section 100 includes a TFT array layer disposed on the flexible substrate 1, and an OLED display layer disposed on the TFT array layer.

Specifically, the plurality of functional devices 300 include a camera and a plurality of sensors.

Specifically, the full-screen display panel further includes a flexible circuit board (FPC) 500 disposed on the backside of the main display section 100, and the FPC 500 is connected to the COP circuit sections 200.

Specifically, the functional devices 300 can be disposed on the FPC 500 on the backside of the main display section 100. On the other hand, the functional devices 300 can be disposed inside an opening defined within the main display section 100.

Specifically, a functional area is corresponding to an area of the plurality of the functional devices 300 disposed on the main display section 100. Each of the COP circuit sections 200 is provided with a drive chip and an external compensation circuit for performing a sectional brightness compensation on the functional area.

Specifically, the plurality of sensors include a fingerprint recognition sensor, a proximity sensor, an ambient light sensor, and a face recognition sensor.

Specifically, the flexible substrate 1 is a polyimide substrate or a bendable flexible substrate made of other materials.

A full-screen display panel of the present invention comprises a main display section 100, and at least two COP circuit sections 200 disposed on different lateral sides of the main display section 100. Because the COP circuit sections 200 are disposed on different lateral sides of the main display section 100, the full-screen display panel has sufficient edge regions for setting external compensation circuits and drive chips, thereby realizing the full-screen display panel with diverse functions.

In summary, a full-screen display of the present invention includes a main display section, and at least two bendable COP circuit sections disposed on different lateral sides of the main display section. The main display section and the COP circuit sections are disposed on a flexible substrate. The COP circuit sections are bent rearwardly from one edge of the main display section to a backside of the main display section, thereby making each of the COP circuit sections attached to the backside of the main display section. Because the COP circuit sections are disposed on different lateral sides of the main display section, the full-screen display panel has sufficient edge regions for setting external compensation circuits and drive chips, thereby realizing the full-screen display panel with diverse functions.

In summary, various other changes and modifications can be made in accordance with the technical solutions and technical concept of the present invention, and all such changes and modifications are within the scope of the claims of the present invention.

What is claimed is:

1. A full-screen display panel, comprising:
a main display section and at least two chip on panel (COP) circuit sections disposed on different lateral sides of the main display section respectively.
wherein the main display section and the COP circuit sections are disposed on a flexible substrate, and each of the COP circuit sections is bent rearwardly from one edge of the main display section to a backside of the main display section, thereby making each of the COP circuit sections attached to the backside of the main display section.

2. The full-screen display panel of claim 1, wherein each of the COP circuit sections comprises:
a first COP circuit section disposed beneath the main display section; and
a second COP circuit section disposed on a left side of the main display section or a right side of the main display section.

3. The full-screen display panel of claim 2, wherein both the first COP circuit section and the second COP circuit section are disposed on the backside of the main display section but do not overlap each other.

4. The full-screen display panel of claim 1, wherein the main display section comprises:
a thin film transistor (TFT) array layer disposed on the flexible substrate; and an OLED display layer disposed on the TFT array layer.

5. The full-screen display panel of claim 1, wherein the full-screen display device further comprises a plurality of functional devices disposed on the backside of the main display section or inside the main display section;
wherein each of the functional devices comprises a camera and a plurality of sensors.

6. The full-screen display panel of claim 5, wherein the full-screen display device further comprises a flexible circuit board disposed on the backside of the main display section, and the flexible circuit board is connected to the COP circuit sections;
wherein the functional devices are disposed on the flexible circuit board on the backside of the main display section.

7. The full-screen display panel of claim 5, wherein the functional devices are disposed inside an opening, and the opening is defined within the main display section.

8. The full-screen display panel of claim 1, wherein a functional area is corresponding to an area of the plurality of the functional devices disposed on the main display section;
wherein the COP circuit section is provided with a drive chip and an external compensation circuit for performing a sectional brightness compensation on the functional area.

9. The full-screen display panel of claim 5, wherein the plurality of sensors include a fingerprint recognition sensor, a proximity sensor, an ambient light sensor, and a face recognition sensor.

10. The full-screen display panel of claim 1, wherein the flexible substrate is a polyimide substrate.
